(19) United States
(12) Patent Application Publication
(10) Pub. No.: US 2024/0353449 A1
(43) Pub. Date: Oct. 24, 2024

(54) INTERLEAVED DIGITAL TRIGGER CORRECTION

(71) Applicant: Tektronix, Inc., Beaverton, OR (US)

(72) Inventor: Joshua J. O'Brien, Aloha, OR (US)

(21) Appl. No.: 18/641,307

(22) Filed: Apr. 19, 2024

Related U.S. Application Data
(60) Provisional application No. 63/461,126, filed on Apr. 21, 2023.
(60) Provisional application No. 63/461,129, filed on Apr. 21, 2023.

(51) Int. Cl. G01R 13/02

(52) U.S. Cl. CPC G01R 13/0254; G01R 13/029

(57) ABSTRACT

A test and measurement instrument includes an array of data pipes, in which each of the array of data pipes further includes an input coupled to an output of an interleaved Analog-to-Digital Converter (ADC), a hysteresis processor coupled to the input to receive a present pipe data value, and coupled to another hysteresis processor in the array of data pipes to receive a previous data value and a previous data direction, the hysteresis processor structured to perform a comparison of the present pipe data value to the previous data value to determine whether a magnitude of a difference between the present pipe data value and the previous data value exceeds a hysteresis value, and a pipeline trigger comparator. Methods are also described.

### CROSS-REFERENCE TO RELATED APPLICATIONS

This disclosure claims benefit of U.S. Provisional Application No. 63/461,126, titled “INTERLEAVED DIGITAL TRIGGER CORRECTION,” filed on Apr. 21, 2023, and claims benefit of U.S. Provisional Application No. 63/461,129, titled “ALIASED HYSTERESIS INTERLEAVED DIGITAL TRIGGER CORRECTION,” filed on Apr. 21, 2023, the disclosures of both of which are incorporated herein by reference in their entirety.

### TECHNICAL FIELD

This disclosure relates to test and measurement instruments, such as oscilloscopes, and more particularly to a trigger system and methods for precision triggering in a test and measurement instrument.

### BACKGROUND

Most modern oscilloscopes have replaced analog-based triggers with digital triggers, which are rapidly becoming the industry standard. Triggers, in either analog or digital form, are used by oscilloscopes to determine what portion or portions of the signals input to a test and measurement instrument are to be captured for analysis. Initially, the oscilloscope stores the data received at its input in a temporary buffer. The data stored in the buffer is overwritten as the incoming data exceeds the size of the buffer. A triggering event causes the instrument to store the data from the temporary buffer elsewhere in the instrument as a sampled waveform for analysis. The sampled waveform may include data that was stored in the temporary buffer before the triggering event occurred, so that the user can evaluate the device being tested, or Device Under Test (DUT), in a state prior to the triggering event as well as during and after the triggering event.

High-performance oscilloscopes use a series, or array, of interleaved Analog-to-Digital Converters (ADCs) to achieve higher effective sample rates than is possible when using only a single ADC for each input channel. As the number of interleaved ADCs increases, it is becoming increasingly difficult to transmit all of the data from the ADCs to a centralized trigger processor, as the incoming data width is simply too large to route to one physical location. For example, in some conventional high-bandwidth instruments, demultiplexers are used to deinterleave the interleaved ADCs. These multiplexers are typically embodied by a Field-Programmable Gate Array (FPGA) or Application Specific Integrated Circuit (ASIC) that supports digital triggers and storage of the ADC data as well as performing other digital processing functions. As data sample rates and resolutions increase, these demultiplexers have practical limits on how many data pipes they can process and store. Also, there is a practical limit to how much output the various demultiplexers can send to a centralized location to perform triggering functions.

For these reasons, some oscilloscopes have started including digital triggers in the data pipeline of each individual ADC. The digital trigger in each data pipeline, however, is exposed to under-sampled data because each ADC is only exposed to a portion of the incoming data. Any frequency above the Nyquist frequency of the individual pipes is aliased. Triggering on the aliased data works for certain types of data, but is not accurate for single pulses at a very high bit rate or for high frequency Radio Frequency (RF) applications, for example.

Embodiments address these and other limitations in the state of the art.

### BRIEF DESCRIPTION OF THE DRAWINGS

FIG. 1 is a block schematic diagram of a test and measurement instrument including an interleaved digital trigger error corrector according to embodiments of the disclosure.

FIG. 2 is a block schematic diagram illustrating a first architecture having multiple ADCs each including a digital pipe trigger that receives information from another digital pipe trigger, according to embodiments of the disclosure.

FIG. 3 is a block schematic diagram illustrating a second architecture having multiple ADCs each including a digital pipe trigger that receives information from another digital pipe trigger, according to embodiments of the disclosure.

FIG. 4 is a block schematic diagram illustrating one pipe trigger processor with hysteresis and direction processing according to embodiments of the disclosure.

FIG. 5 is a block schematic diagram illustrating how multiple data input pipes from multiple ADCs may share hysteresis and direction information for enhanced trigger processing according to embodiments of the disclosure.

FIG. 6 is a schematic diagram illustrating example logic structure for the hysteresis/direction block illustrated in FIGS. 4 and 5 according to embodiments of the disclosure.

### DESCRIPTION OF EMBODIMENTS

Embodiments of the disclosure include an array of individual digital trigger processors in data pipes that pass hysteresis and direction information from neighboring pipes in a ring communication network structure. The hysteresis and direction information allows the trigger processor in each pipe to reduce the number of false triggers that may be caused by noise and generally improves the performance of the digital triggers by accurately triggering on actual triggered events all while, unlike conventional methods, each individual digital trigger processor sees only a portion of the input signal due to the interleaved manner in which the input data is acquired.

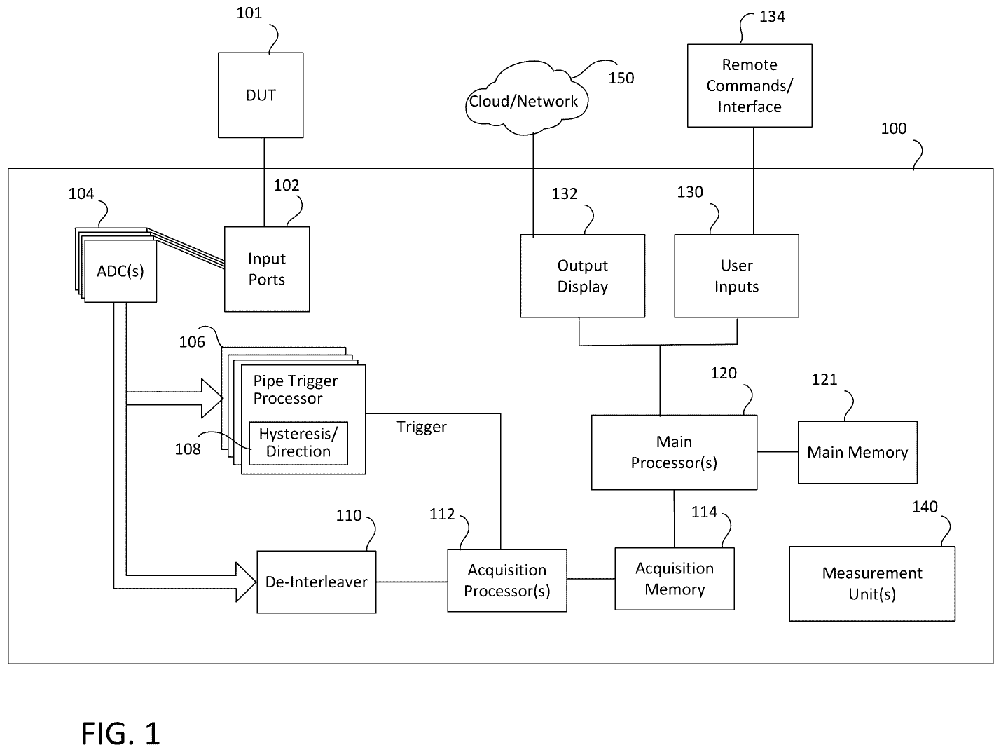

FIG. 1 is an example block diagram of a test and measurement instrument 100 having interleaved digital trigger correction according to some embodiments of the disclosure. The test and measurement instrument 100 includes one or more ports 102, which may be any electrical or optical signaling medium. Ports 102 may include receivers, transmitters, and/or transceivers. Each port 102 is a channel of the test and measurement instrument 100. In some embodiments the test and measurement instrument 100 includes 8, 16, or more separate ports. The test and measurement instrument 100 may couple to a Device Under Test (DUT) 101 through one or more ports 102. DUTs 101 that have multiple outputs may connect each output to the instrument 100 through multiple, independent ports 102.

The input signals received at the ports 102 are then sent to interleaved analog-to-digital converters (ADCs) 104. The interleaved ADCs 104 convert an analog signal received through the one or more ports 102 to digital data that represents the input signal. Interleaving ADCs means that each individual ADC of the interleaved ADCs 104 processes only a portion of the data from the input port 102. The ADCs 104 have a sampling rate that is sufficient to sample the input signals with enough resolution to be usable by the instrument 100, and may be 8-bit, 12-bit, or higher resolution ADCs 104. Output data from the interleaved ADCs 104 is recombined in a de-interleaver 110 to produce the full-bandwidth signal received by the instrument 100.

In some embodiments, each ADC of the interleaved ADCs 104 is also individually coupled to a respective pipe trigger processor 106, so that there is one pipe trigger processor for each of the interleaved ADCs 104. Embodiments of the disclosure also include communication between neighboring pipe trigger processors 106. Specifically, information about a hysteresis level and which direction the data in from the input is progressing, i.e., either higher or lower, is passed in a ring fashion across the group of pipe trigger processors 106 using an array of hysteresis and direction processing blocks 108, as described in detail below. An output of the group of pipe trigger processors 106 is a trigger signal, which may be used by the acquisition processor 112 to determine which information from the DUT is stored in an acquisition memory 114 as an input waveform for measuring and testing the DUT.

The acquisition memory 114 may be a relatively large memory that is structured to quickly store large amounts of incoming data. The acquisition memory 114 may be implemented as volatile memory or as solid-state memory, such as a solid-state disk drive(s).

The instrument 100 also includes one or more main processors 120 configured to execute instructions from main memory 121 and may perform any methods and/or associated steps indicated by such instructions.

User inputs 130 are coupled to the one or more processors 120, and may include a keyboard, mouse, touchscreen, and/or any other controls employable by a user to interact with a GUI on an output display 132. In some embodiments the user inputs 130 may be connected to or controlled by a remote interface 134, so that a user may control operation of the instrument 100 in a remote location physically away from the instrument. The display 132 may be a digital screen such as an LCD, or any other monitor to display waveforms, measurements, and other data to a user. In some embodiments, the output display 132 is also located remote from the instrument 100.

One or more measurement units 140 are illustrated as being part of the instrument 100. These measurement units 140 perform the main functions of measuring parameters and other qualities of signals from the DUT 101 being measured by the instrument 100. Typical measurements include measuring voltage, current, and power of input signals in the time domain, as well as measuring features of the input signals in the frequency domain. The measurement units 140 represent any measurements that are typically performed on test and measurement instruments.

While the components of the test and measurement instrument 100 are depicted as being integrated within test and measurement instrument 100, it will be appreciated by a person of ordinary skill in the art that any of these components can be external to the test and measurement instrument 100 and can be coupled to the test and measurement instrument 100 in any conventional manner (e.g., wired and/or wireless communication media and/or mechanisms). For example, in some examples, the display 132 may be remote from the test and measurement instrument 100, or data or images from the output of the instrument may be made available to other devices through a cloud or other type of communication network 150.

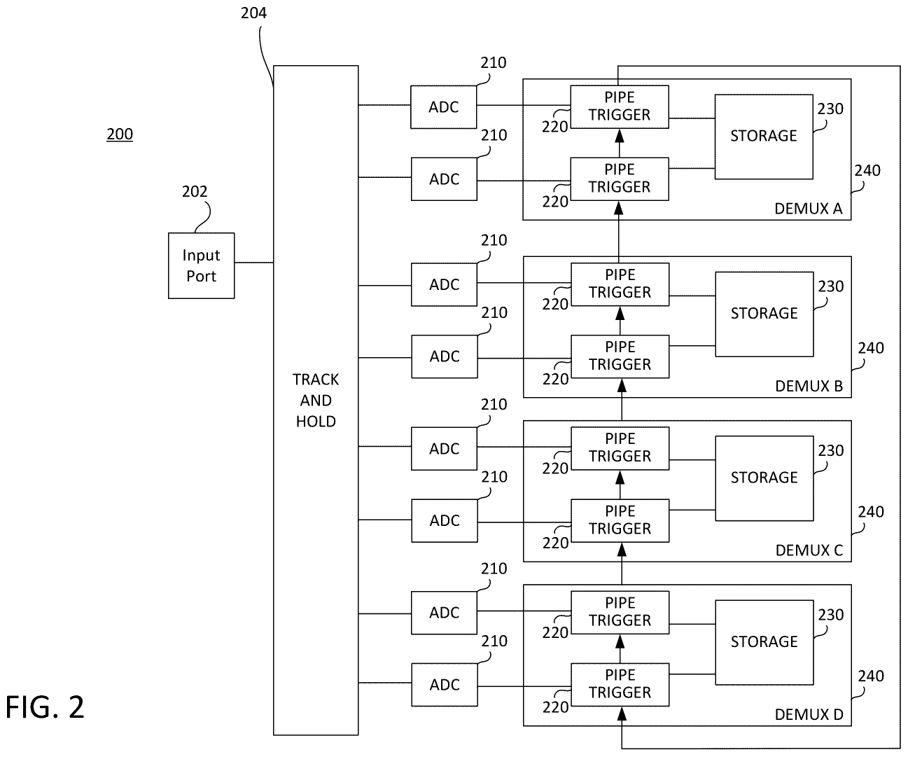

FIG. 2 is a block schematic diagram illustrating a first front-end trigger architecture 200 having multiple ADCs 210, in which each ADC includes a digital pipe trigger 220 that receives information from another digital pipe trigger in the architecture, according to embodiments of the disclosure. The front-end architecture 200 of FIG. 2 describes hardware and processes that are generally located between the input port 102 and the acquisition processor 112 of FIG. 1, although some embodiments may include additional components.

In the front-end trigger architecture 200, an input port 202 is coupled to a track and hold circuit 204, which temporarily stores the input signal long enough to be sampled by the ADCs 210. Similar to the system described above with reference to FIG. 1, the ADCs 210 are interleaved, with each individual ADC sampling only a portion of the input received at the input port 202.

The sample output from each ADC 210 is fed to a pipe trigger 220, which functions to determine whether the portion of the input sampled by its connected ADC exceeds a trigger threshold. As described above, with aliased data above the Nyquist frequency, some types of triggers are difficult to detect. Embodiments of the disclosure allow even difficult triggers to be accurately detected by passing information about adjacent data pipes from one pipe to another in a ring fashion, such as illustrated in FIG. 2. In particular embodiments, the passed information includes hysteresis information and direction information, which are described in detail below.

This ring topology, such as illustrated in FIG. 2, saves significant amounts of data routing compared to conventional solutions where individual trigger blocks are located in different physical devices and then routed to a central trigger. Using the ring topology, embodiments of the disclosure provide sufficient data for each pipe trigger to accurately detect triggering events.

In FIG. 2, four demultiplexers 240 are illustrated, each including two pipe triggers 220 and memory storage 230 for storing sample and trigger data. The demultiplexers 240 perform at least a portion of the de-interleaving function described with reference to FIG. 1. And oftentimes in high-performance instruments, demultiplexers, such as the demultiplexers 240 are located in different physical devices. Using the front-end trigger architecture 200 of FIG. 2, it is unnecessary to route large amounts of data to a centralized decision-making trigger circuit. Instead, embodiments route a minimum amount of data to allow the pipe triggers to operate in a distributed fashion, eliminating the data bottlenecks that centralized triggers face.

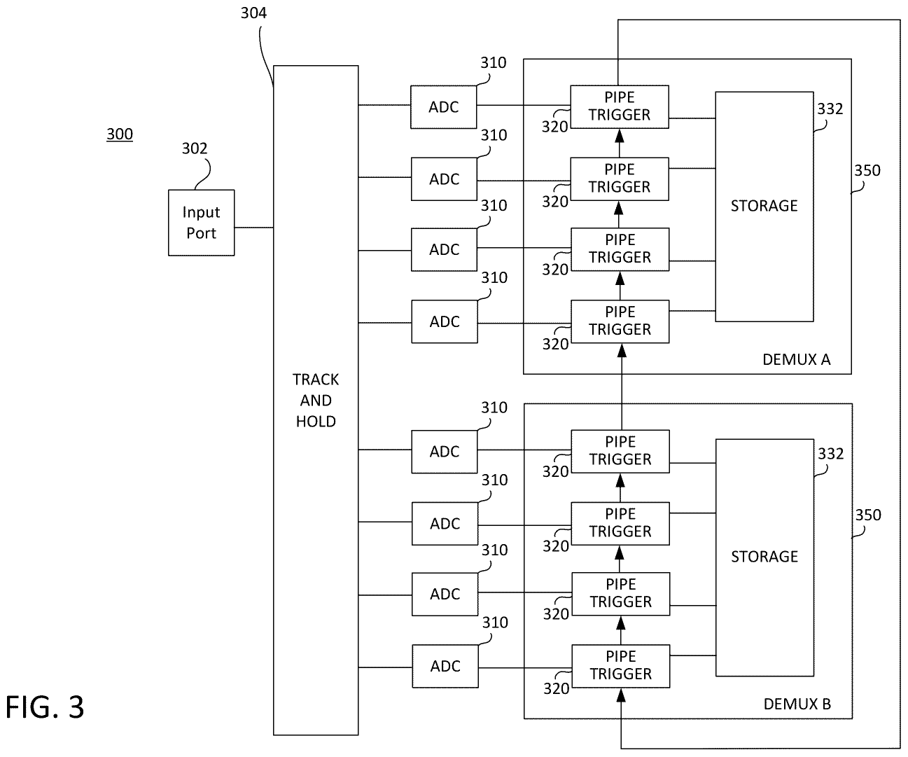

FIG. 3 illustrates a front-end trigger architecture 300 that is similar to the front-end architecture 200 of FIG. 2, except that the front-end trigger architecture 300 includes two demultiplexers 350, each of which contain four pipe triggers 320. Similar to the pipe triggers 220 of FIG. 2, each pipe trigger 320 is fed by a single ADC 310. The ring topology of sending a small amount of data between adjacent pipes is similar to that of the front-end trigger architecture 200, except in the number of data connections that are located outside the demultiplexers 350. In other words, the communication of the ring topology between the four pipe triggers 320 in demultiplexer 350 “Demux A” are all internally connected within the Demux A device. Therefore, in the front-end architecture 300, the ring topology that sends data from one pipe to another includes only two ring connections that are outside of the Demuxes 350—one from a pipe in Demux A (the topmost) sending information to a pipe in Demux B (the bottommost). Similarly, the second outside ring connection is the one from a pipe in Demux B (the topmost) sending information to a pipe in Demux A (the bottommost). By comparison, the front-end architecture 200 of FIG. 2 includes 4 outside data connections in its ring architecture, those being between each of Demux A, Demux B, Demux C, and Demux D. As mentioned above, even with several outside connections, the data carried by the ring topology is very small, and this ring topology saves significant data routing data between demultiplexers when the individual pipes are located in different physical devices.

When implemented in hardware, each demultiplexer 350 may include up to ten separate pipes from ten different ADCs 310, and thus may include up to ten separate pipe triggers.

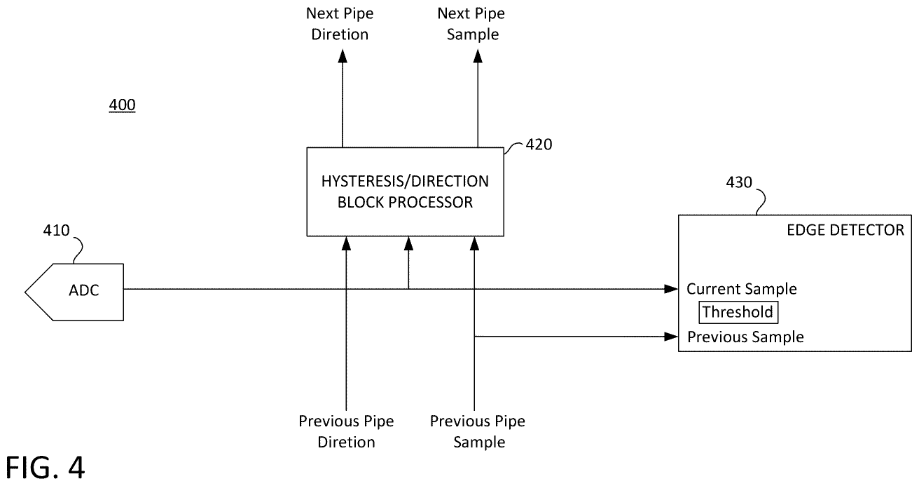

FIG. 4 is a block schematic diagram illustrating main components of a pipe trigger processor 400 with hysteresis and direction processing according to embodiments of the disclosure. The pipe trigger processor 400 of FIG. 4 may be an example of a pipe trigger processor 106 described with reference to FIG. 1.

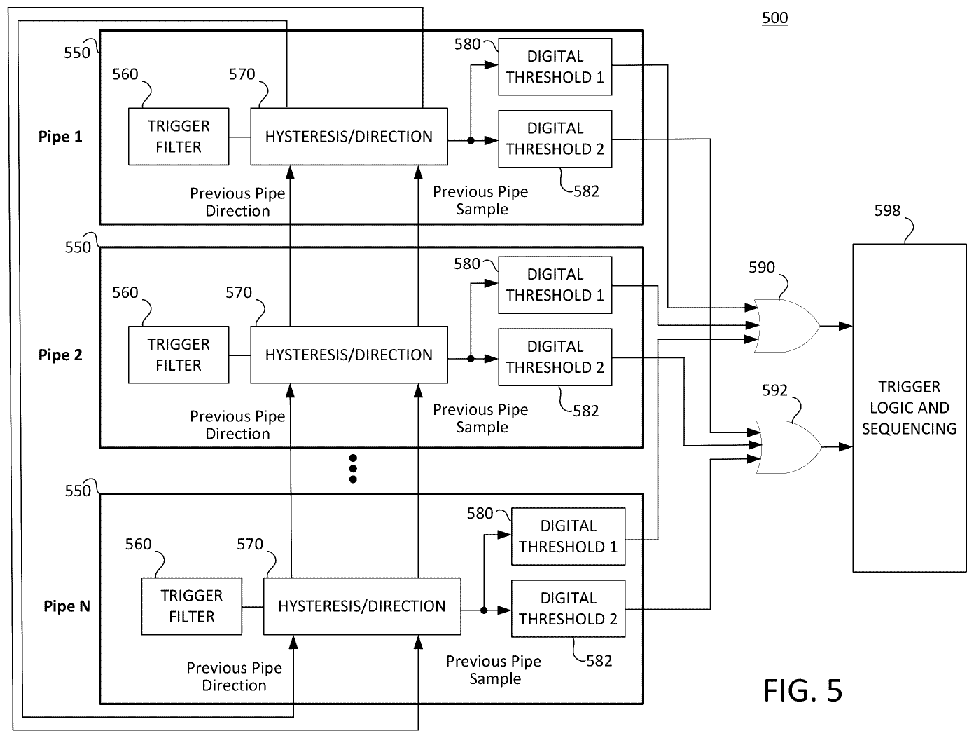

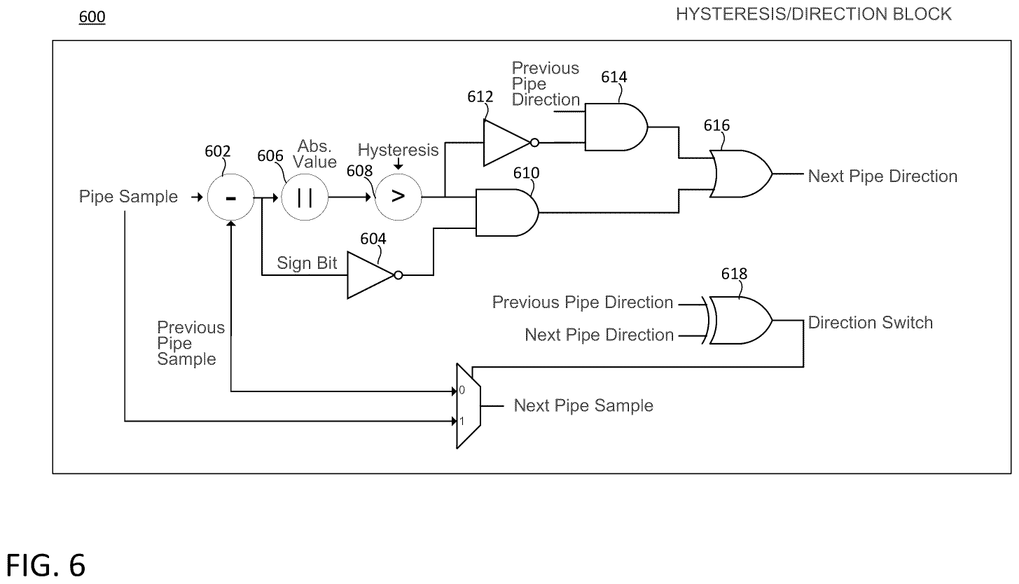

An ADC 410, which is one of a set of interleaved ADCs, generates a current (single) data sample, which is passed to a hysteresis/direction block processor 420 as well as an edge detector 430. The hysteresis/direction block processor 420 accepts two additional inputs—a previous pipe direction and a previous pipe sample. The previous pipe direction may be a single bit of data, in which 0 indicates the previous direction is negative and a 1 indicates the previous direction is positive, although other codings and bit depths may be used. The hysteresis/direction block processor 420 generates and sends two outputs to the next hysteresis/direction block processor 420 in the ring—a next pipe direction and a next pipe sample. Detailed description of how each hysteresis/direction block processor 420 responds to its three inputs to generate its two outputs is described with reference to FIGS. 5 and 6 below.

The edge detector 430 includes comparators to compare the current sample of the present pipe, received directly from the ADC 410, as well as the previous pipe sample, received from the previous hysteresis/direction block processor 420 in the ring, to one or more trigger thresholds. The edge detector 430 generates a trigger signal based on the comparisons, which may be used as a triggering event.

FIG. 5 is a block schematic diagram illustrating a ring structure 500 that shares hysteresis and previous sample information to an adjacent data pipe in the ring. In general, the ring structure 500 illustrates 3 separate data pipes 550 of a system that includes ‘N’ total data pipes. In the ring structure 500, each data pipe 550 in the system generally includes the same components as all of the other data pipes coupled by the ring structure. Meaning, there is no master pipe or master controller that has access to all of the data in all of the pipes. Instead, the hysteresis and trigger processing are distributed among all of the data pipes 550 that are connected by the ring structure 500.

Within each data pipe 550 are a trigger filter 560, a hysteresis/direction block processor 570 described above with reference to FIG. 4, and the details of which are described in FIG. 5, as well as a set of digital threshold comparators 580, 582 that are used to detect trigger events. One difference with the data pipe 550 of FIG. 5 is that there are two digital threshold comparators 580, 582 rather than the single threshold comparator described in reference to the edge detector 430. Embodiments of the disclosure work equally well with any number of threshold comparators, which can be combined in complex ways, such as in the trigger logic and sequencing block 598.

In operation, each data pipe 550 behaves similarly to one another. For example, each trigger filter 560 in each data pipe 550 receives a data sample from a separate ADC (not illustrated). After filtering the sample 560, the sample is passed to the hysteresis/direction block processor 570, which also receives inputs of the previous pipe direction and previous pipe sample from an adjacent data pipe 550. For example, the hysteresis/direction block processor 570 in Pipe 1 receives the previous pipe direction and previous pipe sample from Pipe 2. Similarly, the hysteresis/direction block processor 570 of Pipe 1 sends its previous pipe direction and previous pipe sample to Pipe N, which, in turn, sends its previous pipe direction and previous pipe sample to Pipe N−1.

Also, the present and previous samples are compared to the digital threshold comparators 580, 582, as described above with reference to the edge detector 430 (FIG. 4). Note that, in FIG. 5, each of the outputs of the digital threshold comparators 580, 582 is coupled to individual OR gates 590, 592. In this way the trigger logic and sequencing block 598 receives a signal when any of the threshold comparators indicate that a threshold has been reached. And, since each pipe is making a separate threshold comparison in each of the digital threshold comparators 580, 582, the trigger logic and sequencing block 598 is alerted in the exact cycle when the threshold has been reached.

Embodiments of the disclosure perform specific processing with the hysteresis/direction block processor 570 in each block 550 that allows the digital threshold comparators 580, 582 to be extremely accurate and eliminate sources of error with conventional triggering circuits. Not only does the distributed nature of the ring structure 500 allow each data pipe 550 to independently makes its own data comparisons and generate a signal to the trigger logic and sequencing block 598 as the trigger threshold is reached, without the need to route a large amount of data to a centralized location, but also, the hysteresis/direction block processor 570 plays an important role in ensuring the digital threshold comparators 580, 582 act on actual data rather than possibly triggering on noise or spurious data.

In particular, the hysteresis/direction block processor 570 performs a hysteresis function that implements the following ruleset based on a magnitude and direction of a comparison between the present pipe sample from the trigger filter and the previous pipe sample from the adjacent data pipe, which is referred to in the rule as “the comparison”: if the direction of the comparison is opposite the previous pipe direction, and if the magnitude of the comparison is greater the supplied hysteresis value, then the present pipe sample from the trigger filter is used for the “next pipe sample” output of the hysteresis/direction block processor 570, otherwise, the “previous pipe sample” received from the adjacent data pipe is passed along as the “next pipe sample” output of the hysteresis/direction block processor 570.

This Rule reduces the chance that noise potentially interferes with a triggering comparison, in that, by ensuring that the difference from the previous sample is above a hysteresis value, small disturbances in the ADC or elsewhere due to spurious noise are effectively ignored, which increases the accuracy of the trigger detection by not triggering on false results caused by such noise.

FIG. 6 is a schematic diagram illustrating example logic structure for a hysteresis/direction block processor 600, which may be an embodiment of or similar to the hysteresis/direction block processors described with reference to FIGS. 4 and 5.

There are three inputs to the hysteresis/direction block processor 600 of FIG. 6, which are the same inputs as described above—a) a “pipe sample” received from an ADC (FIG. 4) or trigger filter (FIG. 5), as well as both b) a “previous pipe sample” and c) a “previous pipe direction”, both received from a hysteresis/direction block processor in a previous pipe in the ring (FIG. 5). As described above, the pipe sample and previous pipe samples are sampled input data, while the previous pipe direction is a coded piece of data that indicates the direction that the input sample was moving compared to its previous sample. In some embodiments the coded piece of data may be a single bit indicating the direction.

Also as described above, the hysteresis/direction block processor 600 generates two outputs, which are the “next pipe sample” and “next pipe direction”. The two outputs are functions of the three inputs, as illustrated in FIG. 6 and described below. For clarity, note that the “next pipe sample” and “next pipe direction” in the hysteresis/direction block processor 600 become the “previous pipe sample” and “previous pipe direction” when describing the hysteresis/direction block processor 600 sending this data to the next hysteresis/direction block processor 600 at the conclusion of the present cycle.

In operation, a subtractor 602 subtracts the pipe sample from the previous pipe sample, which generates both an output value and a sign of the subtraction. The sign bit is presented to an inverter 604, while the output value is passed through an absolute value process 606 to generate an output value magnitude. This output value magnitude is compared in a process 608 to the hysteresis value. The hysteresis value may be controllable by the user or may be pre-set based on, for example, the particular signal being measured, or particular measurement being performed by the measurement instrument. In general, the hysteresis value should be set higher than a value of internal noise. The output of the comparison process 608 passes through combinational logic 610, 612, 614, and 616 to generate the “next pipe direction”, which is one of the outputs of the hysteresis/direction block processor 600. Then, the “next pipe direction” just determined is combined in an XOR gate 618 with the “previous pipe direction”, which was input to the hysteresis/direction block processor 600.

Of course, the hysteresis/direction block processor 600 of FIG. 6 is only one of many ways that information about adjacent data pipes may be considered in a particular data pipe. For example, other embodiments could compare a subsequent data value in an adjacent data pipe in the ring rather than the previous value, with only a minor modification of the hysteresis/direction block processor 600. Also, although FIG. 6 illustrates combinational logic, embodiments of the disclosure could use various methods of implementing the functions described therein, such as an ASIC, FPGA, Digital Signal Processor, or a specifically programmed general purpose processor, for example.

With the information of the previous sample and direction, the collection of data pipes, according to embodiments of the disclosure, are able to carefully control which data is stored in each pipe for each cycle-either the newly sampled data in the case of new data exceeding the hysteresis value, or the previous value for cases where it does not. One benefit to such a system is that it automatically eliminates noise in the input section, and, further, when the triggering unit in each data pipe does trigger, there is high confidence that the trigger occurred very close to the actual point in time that the input signal met the threshold value. Therefore, embodiments according to the disclosure increase the accuracy of triggering in high performance measurement instruments.

Embodiments of the disclosure increase the accuracy of the triggering function in a unique way, which is by carefully controlling when to update data values in a particular data pipe based on a comparison of the present data value from an ADC or filter to the previous value from an adjacent pipe. When the comparison is below a hysteresis value, the present data pipe takes the value from the previous pipe, which helps to ensure that noise does not negatively affect the trigger decision process. Other benefits to the triggering system are also presented.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

### Examples

The previously described versions of the disclosed subject matter have many advantages that were either described or would be apparent to a person of ordinary skill. Even so, these advantages or features are not required in all versions of the disclosed apparatus, systems, or methods.

Example 1 is a test and measurement instrument, including an array of data pipes, in which each of the array of data pipes includes: an input coupled to an output of an interleaved Analog-to-Digital Converter (ADC), a hysteresis processor coupled to the input to receive a present pipe data value, and coupled to another hysteresis processor in the array of data pipes to receive a previous data value and a previous data direction, the hysteresis processor structured to perform a comparison of the present pipe data value to the previous data value to determine whether a magnitude of a difference between the present pipe data value and the previous data value exceeds a hysteresis value, and a pipeline trigger comparator.

Example 2 is a test and measurement instrument according to Example 1, in which the pipeline trigger comparator is structured to compare the present pipe data value and the previous data value to a trigger threshold.

Example 3 is a test and measurement instrument according to any of the preceding Examples, in which an output of the pipeline trigger comparator of each data pipe in the array of data pipes is coupled to an OR gate that is further coupled to a trigger processor.

Example 4 is a test and measurement instrument according to any of the preceding Examples, in which the hysteresis processors in the array of data pipes are coupled to one another in a ring network.

Example 5 is a test and measurement instrument according to any of the preceding Examples, in which the hysteresis processor is structured to pass the previous data value received from a first adjacent hysteresis processor to a second adjacent hysteresis processor when the magnitude of the difference between the present pipe data value and the previous data value is less than the hysteresis value.

Example 6 is a test and measurement instrument according to any of the preceding Examples, in which the hysteresis processor is structured to pass the present pipe data value to the second adjacent hysteresis processor when the difference between the present pipe data value and the previous data value is greater than the hysteresis value so long as the previous data direction is opposite a direction output of the difference between the present pipe data value and the previous data value.

Example 7 is a test and measurement instrument according to any of the preceding Examples, in which the hysteresis value is selected by a user of the test and measurement instrument.

Example 8 is a test and measurement instrument according to any of the preceding Examples, in which the hysteresis value is greater than an internal noise value of the test and measurement instrument.

Example 9 is a test and measurement instrument according to any of the preceding Examples, in which the pipeline trigger comparator is configured to make a comparison to the present pipe data value to a first trigger threshold and to a second trigger threshold.

Example 10 is a method in test and measurement instrument, the method including, in each of an array of data pipes, accepting a present pipe data value from an input coupled to an output of an interleaved Analog-to-Digital Converter (ADC), comparing the present pipe data value to a previous data value received from an adjacent data pipe in the array of data pipes to generate a result direction and a result magnitude of the comparison, comparing the result magnitude to a hysteresis value, based on the hysteresis value comparison, passing either the present pipe data value or the previous data value as a next data value to an adjacent data pipe in the array of data pipes, and performing a trigger comparison.

Example 11 is a method according to Example 10, in which performing a trigger comparison comprises comparing the present pipe data value and the previous data value to a trigger threshold.

Example 12 is a method according to any of the preceding Example methods, further comprising indicating a trigger event for the array of data pipes when any of the trigger comparisons in the array of data pipes generates a positive trigger result.

Example 13 is a method according to any of the preceding Example methods, in which each data pipe in the array of data pipes is coupled to one another in a ring network.

Example 14 is a method according to any of the preceding Example methods, further comprising, when the result magnitude is less than the hysteresis value, passing the previous pipe value to a second adjacent data pipe.

Example 15 is a method according to Example 14, further comprising, passing the present pipe data value to the second adjacent data pipe only when the result magnitude is greater than the hysteresis value and a previous data direction indication received from the adjacent data pipe does not match the result direction.

Example 16 is a method according to any of the preceding Example methods, further comprising accepting the hysteresis value from a user of the test and measurement instrument.

Example 17 is a method according to any of the preceding Example methods, in which the hysteresis value is greater than an internal noise value of the test and measurement instrument.

Example 18 is a method according to any of the preceding Example methods, in which performing a trigger comparison comprises making a comparison to a first trigger threshold and to a second trigger threshold.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

We claim:

1. A test and measurement instrument, comprising:
an array of data pipes, in which each of the array of data pipes includes:
an input coupled to an output of an interleaved Analog-to-Digital Converter (ADC),
a hysteresis processor coupled to the input to receive a present pipe data value, and coupled to another hysteresis processor in the array of data pipes to receive a previous data value and a previous data direction, the hysteresis processor structured to perform a comparison of the present pipe data value to the previous data value to determine whether a magnitude of a difference between the present pipe data value and the previous data value exceeds a hysteresis value, and
a pipeline trigger comparator.

2. The test and measurement instrument according to claim 1, in which the pipeline trigger comparator is structured to compare the present pipe data value and the previous data value to a trigger threshold.

3. The test and measurement instrument according to claim 1, in which an output of the pipeline trigger comparator of each data pipe in the array of data pipes is coupled to an OR gate that is further coupled to a trigger processor.

4. The test and measurement instrument according to claim 1, in which the hysteresis processors in the array of data pipes are coupled to one another in a ring network.

5. The test and measurement instrument according to claim 1, in which the hysteresis processor is structured to pass the previous data value received from a first adjacent hysteresis processor to a second adjacent hysteresis processor when the magnitude of the difference between the present pipe data value and the previous data value is less than the hysteresis value.

6. The test and measurement instrument according to claim 1, in which the hysteresis processor is structured to pass the present pipe data value to the second adjacent hysteresis processor when the difference between the present pipe data value and the previous data value is greater than the hysteresis value so long as the previous data direction is opposite a direction output of the difference between the present pipe data value and the previous data value.

7. The test and measurement instrument according to claim 1, in which the hysteresis value is selected by a user of the test and measurement instrument.

8. The test and measurement instrument according to claim 1, in which the hysteresis value is greater than an internal noise value of the test and measurement instrument.

9. The test and measurement instrument according to claim 1, in which the pipeline trigger comparator is configured to make a comparison to the present pipe data value to a first trigger threshold and to a second trigger threshold.

10. A method in test and measurement instrument, the method comprising:
in each of an array of data pipes,
accepting a present pipe data value from an input coupled to an output of an interleaved Analog-to-Digital Converter (ADC),
comparing the present pipe data value to a previous data value received from an adjacent data pipe in the array of data pipes to generate a result direction and a result magnitude of the comparison,
comparing the result magnitude to a hysteresis value,
based on the hysteresis value comparison, passing either the present pipe data value or the previous data value as a next data value to an adjacent data pipe in the array of data pipes, and
performing a trigger comparison.

11. The method according to claim 10, in which performing a trigger comparison comprises comparing the present pipe data value and the previous data value to a trigger threshold.

12. The method according to claim 10, further comprising indicating a trigger event for the array of data pipes when any of the trigger comparisons in the array of data pipes generates a positive trigger result.

13. The method according to claim 10, in which each data pipe in the array of data pipes is coupled to one another in a ring network.

14. The method according to claim 10, further comprising, when the result magnitude is less than the hysteresis value, passing the previous pipe value to a second adjacent data pipe.

15. The method according to claim 14, further comprising, passing the present pipe data value to the second adjacent data pipe only when the result magnitude is greater than the hysteresis value and a previous data direction indication received from the adjacent data pipe does not match the result direction.

16. The method according to claim 10, further comprising accepting the hysteresis value from a user of the test and measurement instrument.

17. The method according to claim 10, in which the hysteresis value is greater than an internal noise value of the test and measurement instrument.

18. The method according to claim 10, in which performing a trigger comparison comprises making a comparison to a first trigger threshold and to a second trigger threshold.
